(19) United States
(12) Patent Application Publication
(10) Pub. No.: US 2020/0328730 A1
(43) Pub. Date: Oct. 15, 2020

(54) SELF-POWERED SWITCHING DEVICE AND OPERATING METHOD FOR SUCH A DEVICE

(71) Applicant: Exagan, Grenoble Cedex (FR)

(72) Inventors: Gérald Augustoni, Puyloubier (FR); Laurent Guillot, Seysses (FR); Thierry To, Seysses (FR)

(21) Appl. No.: 16/954,054

(22) PCT Filed: Dec. 5, 2018
(86) PCT No.: PCT/FR2018/053111

§ 371 Date: Jun. 15, 2020

(30) Foreign Application Priority Data
Dec. 15, 2017 (FR) 1762221

(51) Int. Cl. H03K 3/012; H03K 17/687; G05F 1/46

(52) U.S. Cl. CPC H03K 3/012; G05F 1/46; H03K 17/687

(57) ABSTRACT

A switching device of a load comprises: two switching terminals; a depletion-mode high-voltage transistor and an enhancement-mode low-voltage transistor arranged in series between the two switching terminals and defining a midpoint; a control circuit generating a control signal of the gate of the low-voltage transistor in order to selectively place the device in an on state or in an off state; a power-supply circuit comprising an input connected to the midpoint and an output for supplying a power voltage to the control circuit. The power-supply circuit comprises a reservoir capacitance connected to a normally-on switch for charging the reservoir capacitance and supplying the power voltage to the control circuit when the switching device is connected to the load.

### CROSS-REFERENCE TO RELATED APPLICATIONS

This application is a national phase entry under 35 U.S.C. § 371 of International Patent Application PCT/FR2018/053111, filed Dec. 5, 2018, designating the United States of America and published as International Patent Publication WO 2019/115913 A1 on Jun. 20, 2019, which claims the benefit under Article 8 of the Patent Cooperation Treaty to French Patent Application Serial No. 1762221, filed Dec. 15, 2017.

### TECHNICAL FIELD

The present disclosure relates to a switching device of an electrical load. More specifically, it is aimed at a switching device comprising a control circuit and a power-supply circuit of this control circuit.

### BACKGROUND

Switching devices of a load that combine, in series, a depletion-mode high-voltage transistor and an enhancement-mode low-voltage transistor are known in the art. The transistors are controlled to selectively place the device in an on state for conduction or in an off state, in accordance with the value of an external switching signal applied to a pin of the device. The switching device is intended for integration into a system in which it is electrically connected to a load consisting of a power circuit and a generator, and makes it possible to transfer power from the generator to the power circuit during the conductive periods. The voltage supplied by the generator is usually high, for example, 400 V, 600 V or more.

The two transistors may be mounted in a cascode, in which case the source of the low-voltage transistor is electrically connected to the gate of the high-voltage transistor. A control circuit of the device may selectively place this device in an on state or an off state by way of a control signal applied to the gate of the low-voltage transistor.

The two transistors may alternatively be mounted in a cascade, in which case the control circuit generates a first and a second control signal, which are applied to the gate of the low-voltage transistor and to the gate of the high-voltage transistor, respectively, so as to place this device selectively in the on state or the off state.

In both cases, the switching device is normally off; in other words, when there is no power to the device, in particular, when there is no power to the control circuit, the switching device is in an inactive mode, in the off state. This avoids closing the device to the load in an untimely manner, potentially causing serious safety problems.

Aside from its functions of controlling the conduction state of the switching device, the control circuit ensures good functionality of the device. If a fault or an event liable to cause such a fault is detected, it generates the control signal or signals to place the device in an inactive mode in which it is switched off. This is the case, in particular, if the operating temperature of the device is too high or if particular voltages deviate from the associated set-point voltages.

The control circuit is implemented in integrated form, for example, in the form of a system of programmable logic gates, in the form of discrete components or in the form of a suitably programmed microcontroller. In all cases, the control circuit implements the appropriate sequencing of the control signals in accordance with the value of an external switching signal and the internal state of the device.

The control circuit has to be supplied with electrical power, and for this purpose the device is usually provided with a supply pin, to which a power voltage from a dedicated circuit of the system is applied. This circuit implements high-voltage components such as diodes, inductors and/or capacitors so as to draw power from the switched load of the system and so as to process this power to provide the device with a stable power voltage of relatively low amplitude (a few volts). An external power-supply circuit of this type is complex to implement and expensive.

EP0585788 discloses a switching device of an electrical load comprising a control circuit supplied at low voltage by the secondary coil of an external transformer. A starter circuit makes it possible to initiate the startup of the control circuit and electrical power supply during operation of the switching device that requires the voltage supplied by the secondary of the transformer.

Some prior art documents provide an auxiliary internal power source of a switching device. This is the case, in particular, in U.S. Pat. No. 9,590,507.

### BRIEF SUMMARY

The present disclosure proposes an alternative solution to the prior art solutions. The present disclosure, in particular, involves proposing a switching device of a load, comprising two switching terminals, a depletion-mode high-voltage transistor and an enhancement-mode low-voltage transistor arranged in series between the two switching terminals and defining a midpoint, a control circuit generating a control signal of the gate of the low-voltage transistor in order to selectively place the device in an on state or in an off state, and a power-supply circuit comprising an input connected to the midpoint and an output for supplying a power voltage to the control circuit.

According to the present disclosure, the power-supply circuit comprises a reservoir capacitance establishing the power voltage supplied to the control circuit when the switching device is connected to the load.

According to the present disclosure, the power-supply circuit also comprises a normally-on switch, arranged between the input and the reservoir capacitance and suitable for electrically isolating the reservoir capacitance from the midpoint when it is open.

According to the present disclosure, the reservoir capacitance establishes the power voltage supplied to the control circuit when the switching device is connected to the load, the reservoir capacitance being electrically isolated from the midpoint when the switch is open.

A self-supply circuit of the control circuit is thus provided, and it is not necessary to provide a power-supply circuit external to the device.

According to other advantageous, non-limiting features of the present disclosure, taken alone or in any technically feasible combination:
the gate of the high-voltage transistor is electrically connected to the source of the low-voltage transistor;
the control circuit generates a second control signal of the gate of the low-voltage transistor;
the switch comprises a depletion-mode low-voltage transistor and a diode electrically connected to the input of the circuit and arranged in series with the depletion-mode low-voltage transistor;
the switch comprises a first and a second depletion-mode low-voltage transistor connected in series;
the power-supply circuit further comprises a circuit for regulating the power voltage;
the control circuit is configured to generate a deactivation signal for the switch such that the first control signal is generated to place the device in the on state;
the high-voltage transistor has a threshold voltage greater in absolute value than the power voltage sufficient to render the control device functional;
the control circuit is configured to generate a deactivation signal for the switch when the power voltage (Va) exceeds a threshold voltage;
the control circuit is configured to place the device in a protected configuration when the power voltage falls below a minimum threshold voltage.

The present disclosure further relates to a method for controlling this switching device, the method comprising:
an off phase during which the control circuit generates a control signal to open the low-voltage transistor;
an on phase during which the control circuit generates a control signal to close the low-voltage transistor.

According to the present disclosure, the method comprises the control circuit generating a deactivation signal to open the switch of the power-supply circuit at least during the on phase of the switching device.

### BRIEF DESCRIPTION OF THE DRAWINGS

Further features and advantages of the present disclosure will be apparent from the following detailed description of embodiments of the disclosure with reference to the accompanying drawings, in which:

FIG. 1 shows an example embodiment of a switching device according to the present disclosure;

FIG. 2 is a chronogram of the voltages occurring in a device according to the present disclosure during the operation thereof;

FIGS. 3a to 3d schematically show the state of a device according to the present disclosure in different steps in the operation thereof;

FIG. 4 shows an improved version of a switching device 1 according to the present disclosure;

FIG. 5 shows an example embodiment of a circuit for regulating the power voltage;

FIG. 6 shows a first embodiment of a power-supply circuit according to the present disclosure;

FIGS. 7A to 7D show four other embodiments of a power-supply circuit according to the present disclosure.

### DETAILED DESCRIPTION

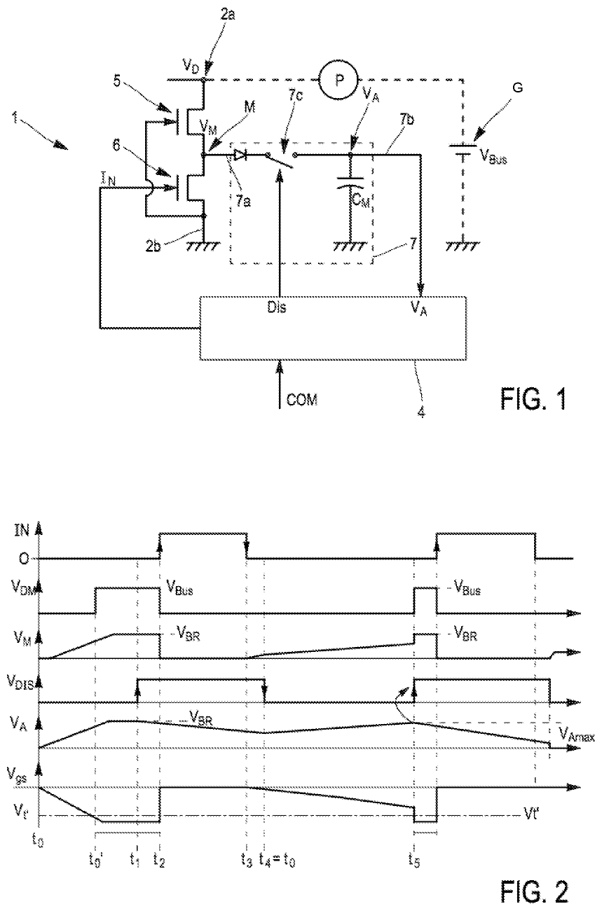

FIG. 1 shows an example embodiment of a switching device 1 according to the present disclosure.

It comprises two switching terminals 2a, 2b, to which there may be connected, as shown in dotted lines in the drawing, a load P and a generator G representing a power circuit to which the switching device 1 is connected. The voltage Vbus of the generator G may be significant, for example, 400 V, 600 V or more, and the current that can flow in the power device may be high, for example, greater than 1 A.

As is well known per se, the switching device 1 makes it possible to apply the voltage of the generator G selectively to the load P in accordance with a switching signal COM that can be applied to a pin of the device so as to be supplied to a control circuit 4. It is also conceivable for this switching signal COM to be generated by the switching device 1 itself, or more specifically by the control circuit 4 of this device 1.

The switching device 1 comprises a depletion-mode high-voltage transistor 5.

A “high-voltage transistor” refers to a transistor comprising a drain, a source and a gate, the low-amplitude voltage (of approximately a few volts) that is applied to the gate making it possible to render the connection between the drain and the source electrically on or off. In the off state, the voltage occurring between the drain and the source may be high-amplitude, for example, 400 V, 600 V or more, without damaging the transistor.

A depletion-mode transistor has a negative voltage threshold (typically between −8 V and −5 V in the context of the present disclosure). The voltage between the gate and the source therefore has to be negative, below this threshold voltage, to render this transistor off.

The depletion-mode high-voltage transistor 5 may be an HEMT transistor, for example, based on GaN or SiC. This type of transistor has an high-amplitude avalanche voltage (in other words the maximum voltage that can be applied between the drain and source of the transistor without damaging it, which may be a breakdown voltage), selected to be greater than the voltage of the generator of the power circuit, for example, greater than 400 V or 600 V.

The switching device 1 further comprises an enhancement-mode low-voltage transistor 6, comprising a drain, a source and a gate.

An enhancement-mode transistor has a positive threshold voltage. The voltage between the grid and the source therefore has to be positive and greater than this threshold voltage so as to render this transistor on.

The low-voltage transistor 6 may be a silicon-based MOSFET transistor. The avalanche voltage of the low-voltage transistor is lower than that of the high-voltage transistor. It may, for example, be approximately 30 V.

The low-voltage transistor 6 and the high-voltage transistor 5 are arranged in series between the two switching terminals 2a, 2b. Thus, the drain of the high-voltage transistor is connected to one of these two terminals, and the source of the low-voltage transistor is connected to the other of these terminals. The source of the high-voltage transistor 5 is connected to the drain of the low-voltage transistor 6 at a midpoint M. In the example shown, the first terminal 2a is connected to the load and the second terminal 2b to an electrical ground of the system, but the present disclosure is by no means limited to this particular configuration.

In the example shown, the low-voltage transistor 6 and the high-voltage transistor 5 are mounted in a cascode; in other words, the source of the low-voltage transistor, here connected to the ground of the system, is also electrically connected to the gate of the high-voltage transistor 5.

In this configuration, the on or off state of the device 1 is determined by the voltage applied to the gate of the low-voltage transistor 6. A voltage above the threshold voltage Vt of this transistor renders it on, and a voltage below this threshold voltage Vt renders it off.

Further to the description of the switching device 1 of FIG. 1, this also comprises a control circuit 4. As has been seen, this circuit can receive a switching signal COM produced outside the device 1. Alternatively, the control circuit 4 may itself produce this switching signal in accordance with the state of the device, in other words from measurements of particular voltages or particular currents drawn from the device, which are communicated to it via electrical connections (not shown in the schematic FIG. 1). Regardless of how the control circuit 4 receives or produces this switching signal COM, the control signal processes this signal to establish and generate a control signal IN that is applied to the gate of the low-voltage transistor 6, so as effectively to place the device 1 in an on or off state.

As has been seen, the control circuit 4 is an active circuit, which therefore needs to be electrically powered. For this purpose, the device 1 is provided with a power-supply circuit 7. This circuit comprises an input 7a electrically connected to the midpoint M defined between the high-voltage transistor 5 and the low-voltage transistor 6. It also has an output 7b, which supplies a power voltage Va and is electrically connected to the control circuit 4. The electrical power voltage Va is of a low value by comparison with the voltages that can occur at the switching terminals 2a, 2b or the midpoint M. It is of approximately a few volts, for example, 5 V.

The power-supply circuit 7 comprises a reservoir capacitance Cm, of which one of the electrodes is connected to the output 7b and the other to the electrical ground of the system or to another reference voltage of this system. This capacitance Cm has the function of storing loads drawn at the midpoint M so as to establish the power voltage Va that will be provided to the control circuit.

The voltage Vm at the midpoint M varies during the operation of the device, between the electrical ground of the system, when the device is on, and the avalanche voltage of the low-voltage transistor, when the device is off.

The power-supply circuit 7 comprises a switch 7c arranged between the input 7a and the terminal of the reservoir capacitance Cm carrying the power voltage Va, corresponding to the output 7b. The switch 7c is normally on; in other words, the switch is closed in the absence of any command, and in this case the reservoir capacitance is connected to the midpoint M of the device 1.

The “normally on” feature of the switch 7c is important because it ensures that, upon startup of the device 1, in other words at the moment when it is placed in electrical contact with the load at the two switching terminals 2a, 2b, the power circuit can draw charge at the midpoint M to fill the reservoir capacitance Cm and develop and provide a sufficient power voltage Va to be able to activate the control circuit 4. The operation of the device will be explained in greater detail later in the present disclosure.

The switch 7c is rendered open by way of a deactivation signal DIS generated by the control circuit 4. When the control circuit 4 is supplied and operational, it establishes and generates the deactivation signal DIS of the switch 7c when the control signal IN is generated so as to place the device 1 in an on state. The power-supply circuit 7 is thus isolated from the high-voltage and low-voltage transistors 5, 6 during this time period. More specifically, the reservoir capacitance Cm is electrically isolated from the midpoint, which is passed through during the conduction phase of the device by a high-intensity current, which must not be diverted toward the power-supply circuit 7.

As is well known per se, the switch 7c may comprise a normally-on transistor, for example, a low-voltage transistor such as a depletion-mode MOSFET transistor. The body diode that is intrinsically present in transistors of this type leads to a reverse current being allowed to flow in the transistor. Because of the presence of this reverse current, a transistor of this type cannot in its own right constitute a switch which, when open, makes it possible to isolate the reservoir capacitance Cm electrically from the midpoint M.

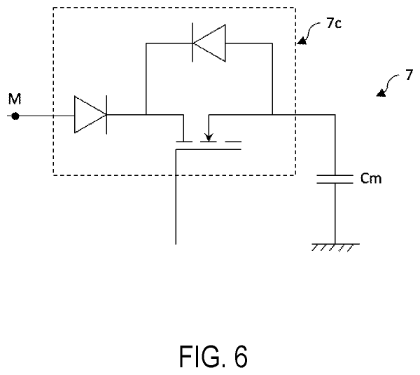

In a first embodiment of the present disclosure, shown in FIG. 6, the switch 7c comprises a depletion-mode low-voltage transistor and a diode that is electrically connected to the input 7a of the circuit and arranged in series with the depletion-mode low-voltage transistor.

The presence of a diode of this type has the advantage of making it possible to avoid discharging the reservoir capacitance Cm into one of the high-voltage and low-voltage transistors 5, 6, and thus to preserve the charge, if the voltage of the midpoint M has fallen below the power-supply voltage available at the terminals of the reservoir capacitance Cm.

In this situation, the series connection of a diode and of the depletion-mode low-voltage transistor makes it possible to isolate the reservoir capacitance Cm electrically from the midpoint.

The depletion-mode low-voltage transistor may be a P-channel transistor. In this case, the drain of the depletion-mode low-voltage transistor is connected to the terminal of the reservoir capacitance Cm, the source thereof to the diode, and the gate thereof to the control circuit 4. Thus, when the depletion-mode low-tension transistor is in an on state, the current flows from the midpoint toward the reservoir capacitance Cm. When the low-voltage depletion-mode transistor is in an off state, the body diode allowing the current to flow from the drain toward the source, the diode blocks the current flowing through the body diode, isolating the reservoir capacitance Cm from the midpoint M.

Alternatively, the depletion-mode low-voltage transistor may be an N-channel transistor. In this case, the source of the depletion-mode low-voltage transistor is connected to the terminal of the reservoir capacitance Cm, the drain thereof to the diode, and the gate thereof to the control circuit 4. Thus, when the depletion-mode low-voltage transistor is in an on state, the current flows from the midpoint toward the reservoir capacitance Cm. When the depletion-mode low-voltage transistor is in an off state, the body diode allowing the current to flow from the source toward the train, the diode blocks the current flowing through the body diode, isolating the reservoir capacitance Cm from the midpoint M.

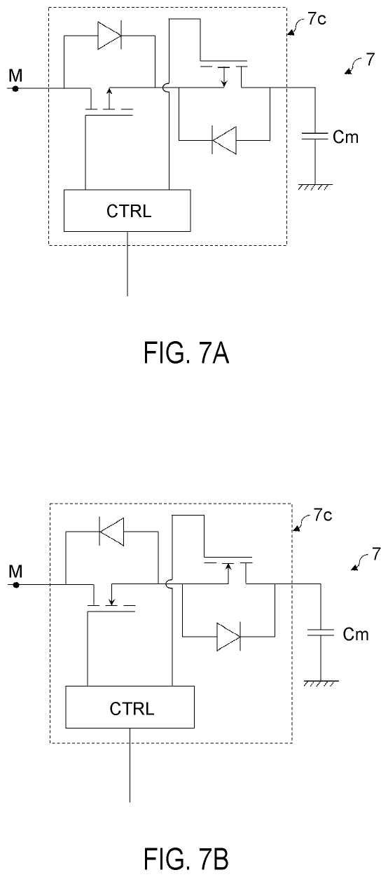

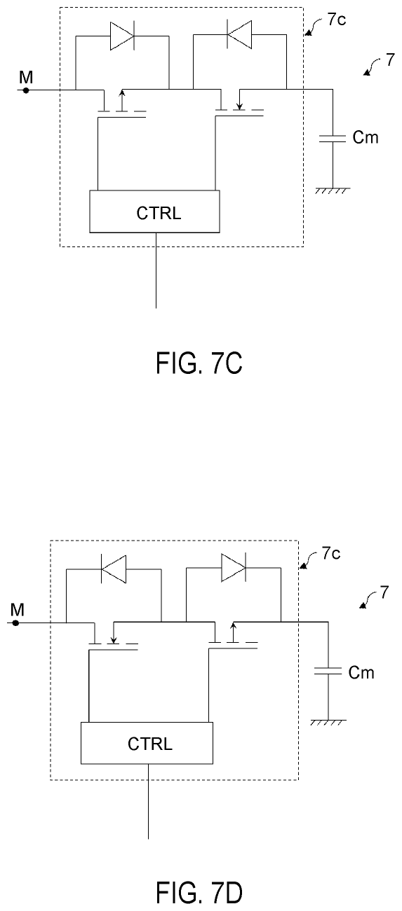

FIGS. 7A to 7D show four other embodiments according to the present disclosure. In these four embodiments, the series connection of the diode and the depletion-mode low-voltage transistor is replaced with a first and a second depletion-mode low-voltage transistor connected in series.

In one embodiment, the first and second depletion-mode low-voltage transistors are two N-channel transistors or two P-channel transistors, the drains of each transistor being interconnected or the sources of each transistor being interconnected.

As is shown in FIG. 7A, the first and second depletion-mode low-voltage transistors may be two P-channel transistors. In this situation, the body diode of each transistor allowing the current to flow from the source toward the drain, these two transistors should be placed back to back. Thus, when the two depletion-mode low-tension transistors are in an on state (in other words the default state thereof), the current flows from the midpoint M toward the reservoir capacitance Cm. When the two depletion-mode low-voltage transistors are in an off state, the body diodes thereof being positioned in opposite directions, the current cannot flow in either direction, isolating the reservoir capacitance Cm from the midpoint M.

Alternatively, as is shown in FIG. 7B, the first and second depletion-mode low-voltage transistors may be two N-channel transistors. In this situation, the body diode of each transistor allowing the current to flow from the drain toward the source, these two transistors should likewise be placed back to back. Thus, when the two depletion-mode low-voltage transistors are in an on state, the current flows from the midpoint M toward the reservoir capacitance Cm. When the two depletion-mode low-voltage transistors are in an off state, the body diodes thereof being positioned in opposite directions, the current cannot flow in either direction, isolating the reservoir capacitance Cm from the midpoint M.

The term “back to back” means that the drains of each transistor are interconnected or the sources of each transistor are interconnected. Thus, in all these configurations, the drain of the first transistor is connected to the midpoint and the source thereof to the source of the second transistor, and the drain of the second transistor is connected to the terminal of the reservoir capacitance Cm.

Naturally, it is possible to reverse the terminals of the first and second transistors, in such a way that the source of the first transistor is connected to the midpoint, the drain thereof is connected to the drain of the second transistor, and the source of the second transistor is connected to the terminal of the reservoir capacitance Cm.

In another embodiment, the first and second depletion-mode low-tension transistors are an N-channel transistor and a P-channel transistor or a P-channel transistor and an N-channel transistor, respectively, the source of the first transistor being connected to the drain of the second transistor.

As is shown in FIG. 7C, the first transistor may be an N-channel transistor and the second transistor a P-channel transistor. In this situation, the body diodes of the N-channel transistor and of the P-channel transistor allowing the current to flow from the source toward the drain and from the drain toward the source, respectively, the two transistors should be placed in series, meaning that the source of the first transistor is connected to the drain of the second transistor. Thus, when the two depletion-mode low-voltage transistors are in an on state, the current flows from the midpoint M toward the reservoir capacitance Cm. When the two depletion-mode low-voltage transistors are in an off state, the body diodes thereof being positioned in opposite directions, the current cannot flow in either direction, isolating the reservoir capacitance Cm from the midpoint M.

Alternatively, as is shown in FIG. 7D, the first transistor may be a P-channel transistor and the second transistor an N-channel transistor. In this situation, the body diodes of the P-channel transistor and of the N-channel transistor allowing the current to flow from the drain toward the source and from the source toward the drain, respectively, the two transistors should be placed in series, meaning that the source of the first transistor is connected to the drain of the second transistor. Thus, when the two depletion-mode low-voltage transistors are in an on state, the current flows from the midpoint M toward the reservoir capacitance Cm. When the two depletion-mode low-voltage transistors are in an off state, the body diodes thereof being positioned in opposite directions, the current cannot flow in either direction, isolating the reservoir capacitance Cm from the midpoint M.

Naturally, the terminals of the first and second transistors may be reversed, in such a way that the source of the first transistor is connected to the midpoint M, the drain of the first transistor is connected to the source of the second transistor, and the drain of the second transistor is connected to the terminal of the reservoir capacitance Cm.

Regardless of the selected embodiment, it is thermally particularly advantageous for the two transistors forming the switch 7c to be in an on state or in an off state simultaneously.

Closing the two transistors simultaneously makes it possible to force the current to pass through the channel of each of them, short-circuiting the body diodes thereof. A short circuit of this type makes it possible to avoid thermal dissipation through the body diodes.

Advantageously, so as to synchronize the on or off state of each of the transistors, the switch 7c may comprise a control box CTRL aimed at adapting the voltage levels supplied to the gates. As is shown in FIGS. 7A to 7D, this box is arranged between the control circuit 4 and the gate of each of the depletion-mode low-voltage transistors. The control box CTRL is configured so as to adapt the signal delivered by the control circuit to apply a voltage to each of the gates so as simultaneously to place both transistors in an on or off state. The configuration of a box of this type is well known per se, and may, for example, comprise, in accordance with the nature of the depletion-mode low-voltage transistors, an inverter.

Regardless of the selected configuration, the switch 7c is in fact a normally-on switch suitable for electrically isolating the reservoir capacitance Cm from the midpoint M when it is open.

By way of illustration, FIG. 2 is a chronogram of the voltages developed in the device 1 during the operation thereof.

Very generally, the device 1 is commanded by the control circuit 4 to alternate:
an off phase, during which the control circuit 4 generates a control signal IN to open the low-voltage transistor 6. This signal is at 0 V in the chronogram of FIG. 2. It is below the threshold voltage Vt of the low-voltage 6 transistor so as to render it off
an on (or conduction) phase, during which the control circuit 4 generates a control signal to close the low-voltage transistor 6. This signal may be of a few volts, but in all cases is greater than the threshold voltage Vt of the low-voltage transistor 6 so as to render it on. During this phase, likewise, the control circuit generates a deactivation signal DIS so that the switch 7c of the power-supply circuit 7 is open.

Returning to the description of FIG. 2, the time t0 is defined as the time at which the device 1 is physically connected to the load thereof. At this time to, the reservoir capacitance Cm is therefore completely discharged, and the power voltage Va is zero. The control circuit 4 is not capable of operating, in other words providing commands such as the command of the gate of the low-voltage transistor IN or the control of the switch DIS. However, the “cascode” configuration of the high-voltage and low-voltage transistors 5, 6 ensures that the device 1 is indeed in an off state.

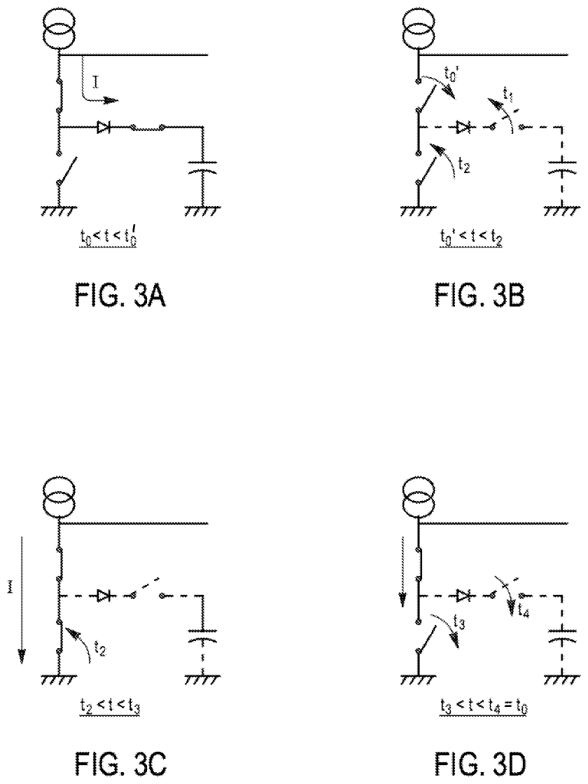

FIG. 3a schematically shows the state of this device at this startup time t0. The control circuit 4 is not powered, the control signal IN has a zero voltage less than the threshold voltage Vt of the enhancement-mode low-voltage transistor, and this transistor is therefore open. The normally-on switch 7c of the power-supply circuit 7 is closed, the control circuit 4 being incapable of providing a deactivation signal DIS. The voltage of the source of the depletion-mode high-voltage transistor 5 (corresponding to the control voltage Vgs of this transistor) is likewise substantially zero at the startup time t0, but still greater than the threshold voltage Vt′ of this transistor (this threshold voltage being negative), which is therefore on. During the moments following the time t0, charge is therefore drawn at the midpoint by virtue of a current I flowing in the high-voltage transistor 5, the reservoir capacitance Cm is charged, and a power-supply voltage Va is gradually established. The voltage at the terminals of the high-voltage transistor VDM, when this is on, is substantially zero (and in any case at least one order of magnitude less than the voltage of the generator Vbus) if the drain-source resistance of this transistor is ignored.

When this power-supply voltage Va is sufficient, for example, when it reaches a nominal supply voltage of the control circuit 4, which may, for example, be 5 V, the control circuit 4 is activated and becomes operational. In other words, the control circuit 4 is thus electrically powered by the power-supply circuit 7, and is therefore operational and ready to generate the commands making it possible to operate the device 1.

Naturally, the threshold voltage Vt′ of the high-voltage transistor has been selected to be greater (in absolute value) than a power-supply voltage Va sufficient for the control circuit 4 to be operational.

The voltage of the midpoint Vm is equivalent to the power-supply voltage. This voltage therefore gradually increases with the power-supply voltage. t0′ designates the moment at which the progression of the voltage of the midpoint is such that the control voltage Vgs (corresponding to the opposite of the voltage Vm of the midpoint) passes below the threshold voltage Vt′ of the high-voltage transistor. From this moment t0′, the high-voltage transistor 5 opens, and the voltage applied between the terminals VDM thereof is established substantially at the voltage of the generator Vbus. However, the leakage current passing across this transistor leads to the voltage continuing to increase from the midpoint as far as the avalanche voltage VBR of the low-voltage transistor 6. The schematic state of the device 1 from this time t0′ is shown in FIG. 3b.

To avoid continuing to charge the reservoir capacitance Vm as far as the avalanche voltage VBR of the low-voltage transistor 6, which could be excessive, it may be provided that the control circuit 4 generates a command for opening the switch DIS upon startup, in such a way that the power-supply voltage Va is sufficient. In the example shown to illustrate the operation of the device 1 in FIGS. 2 and 3b, the control device generates the deactivation signal DIS of the switch 7c at time t1, subsequent to the time at which the midpoint has reached the avalanche voltage VBR of the low-voltage transistor 6. As a result, the switch 7c is open, and the charge of the reservoir capacitance Cm that is drawn to supply the control circuit is not renewed. The power-supply voltage Va is therefore reduced starting from this time t1.

For example, if the switch 7c is formed by the series combination of a depletion-mode low-voltage transistor and a diode, the opening command of the switch DIS may correspond to the application to this transistor of a gate voltage lower than the threshold voltage thereof, causing it to be placed in an off state. The series combination of the diode with the transistor makes it possible to isolate the reservoir capacitance Cm electrically from the midpoint M.

If the switch 7c is formed by the combination of two depletion-mode low-voltage transistors, the command to open the switch DIS may correspond to the application to each of these transistors of a gate voltage less than its threshold voltage, causing them to be placed in an off state. The combination of these two transistors in one of the above-described configurations makes it possible to isolate the reservoir capacitance Cm electrically from the midpoint M.

Alternatively and advantageously, the command to open the switch DIS may correspond to supplying a signal to the control box CTRL, configured to adapt the voltage levels supplied to the gates and to place the depletion-mode low-voltage transistors in an off state simultaneously.

As has already been described above, this simultaneity makes it possible to avoid thermal dissipations across the body diode of a transistor, which would be placed in an off state while the other transistor is in an on state.

At time t2, the control circuit 4 generates a command of the gate of the low-voltage transistor IN aimed at rendering it closed and causing the device 1 to enter a conduction phase. As has been seen, this may be brought about by switchover of the external switching signal COM. The control circuit 4 has ensured that this event is preceded by the deactivation of the switch 7c of the power-supply circuit 7 at time t1, so as to prevent, as has been shown, this circuit from being kept connected to the midpoint M during this phase. Therefore, in general, and if such is not already the case, the control circuit 4 is configured to deactivate the switch 7c of the power-supply circuit by generating an opening control DIS of this switch, before generating the control signal of the low-voltage transistor gate IN to render it closed.

The control circuit 4 generates the control signal IN of the gate of the low-voltage transistor 6 to place the device 1 in an on state for a time period extending until a time t3, as is shown in FIGS. 2 and 3c. Throughout this time period, between times t2 and t3, the control circuit 4 maintains the deactivation signal DIS of the switch 7c in such a way that it is open. The reservoir capacitance Cm therefore continues to discharge as the charge supplying the control circuit is consumed.

At time t3, the control circuit 4 switches the control IN of the gate of the low-voltage transistor 6 to render it open and to interrupt the conduction phase of the device 1. This time t3 may be provoked by the switching of the external switching signal COM to the device 1 or established by the control circuit 4 itself, for example, at the end of a determined duration of the conduction phase.

Shortly after this time t3, the control circuit 4 switches the deactivation signal DIS of the switch 7c, at a time t4, so as to place the reservoir capacitance Cm back in contact with the midpoint M and allow it to recharge. Between times t3 and t4, which are very close to one another, the voltage of the midpoint rises little by little toward the avalanche voltage VBR of the low-voltage transistor 6. The high-voltage transistor 5 is kept closed and, ignoring the drain-source resistance of the high-voltage transistor 5, the voltage applied between the terminals VDM is substantially zero. The state of the device between times t3 and t4 is shown schematically in FIG. 3d.

At time t4, the device is back in a state similar to that of time t0 or t0′. The on and off phases of the device can thus follow on from one another (in accordance with the state of the switching signal COM) and reproduce the cycle, which has just been set out.

In a complementary illustration of the operation of a device 1 according to the present disclosure, FIG. 2 shows a situation where, at a time t5, the deactivation signal DIS of the switch 7c is generated when the power voltage Va reaches a predetermined threshold value Vamax less than the avalanche voltage VBR of the low-voltage transistor 6. This voltage Vamax is selected to be greater than the nominal power voltage of the control circuit 4. To avoid excessively charging the reservoir capacitance, as far as the avalanche voltage VBR of the low-voltage transistor 6, the control circuit is configured to generate the deactivation signal DIS of the switch 7c to open it and stop charging the reservoir capacitance Cm once the power voltage Va supplied by the power-supply circuit 7 exceeds this threshold value Vamax.

It can thus be seen in FIG. 2, starting from this time t5, that opening the switch 7c leads to an abrupt rise in the voltage of the midpoint Vm to the avalanche voltage of the low-voltage transistor VBR. It is also noted that at the same time the gate-source voltage Vgs of the high-voltage transistor 5 passes below the threshold voltage Vt′ of this transistor, leading to it being rendered open and to the voltage of the generator Vbus being applied between its terminals. The electrical consumption of the control circuit 4 continues, leading to the power supply voltage Va supplied by the power-supply circuit being lowered.

In a variant that is not shown, it may equally be provided that the control circuit is configured to detect the power voltage Va passing below a predetermined minimum threshold value Vamin. Below this threshold power voltage, proper operation of the control circuit is no longer guaranteed. Also, the control circuit is configured in such a way that this detection leads to the device 1 passing into a protected configuration. This may, for example, involve keeping or switching the control signal of the gate of the low-voltage transistor 6 in or into an open state once the power voltage falls below this minimum threshold Vamin. The device 1 is thus place in a protected off state.

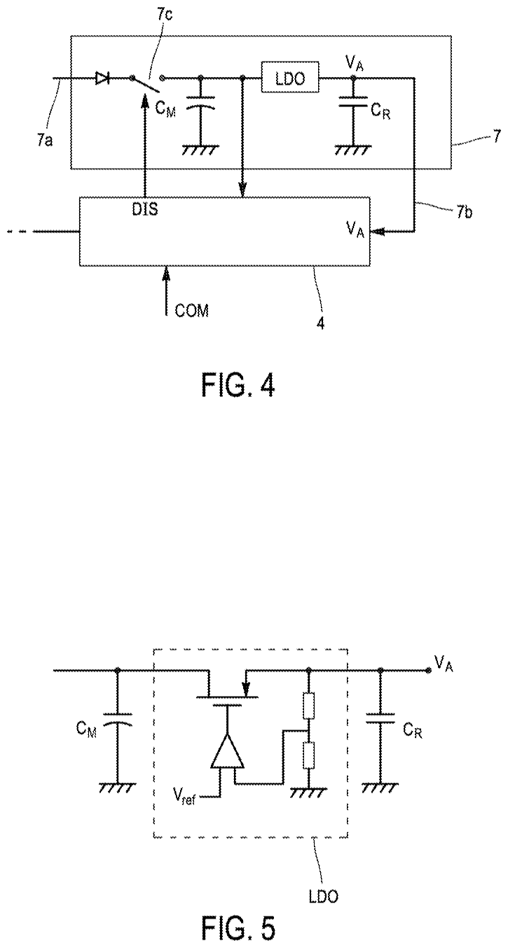

FIG. 4 shows an improved version of a switching device 1 according to the present disclosure, on which the high-voltage 5 and low voltage 6 transistors have been omitted for improved clarity.

Aside from the elements already described in connection with the device of FIG. 1, the power-supply circuit 7 of the improved version of the device 1 comprises, in the power-supply circuit, a voltage regulator LDO arranged between the reservoir capacitance Vm and a regulated capacitance Cr that is connected to the output 7b of the circuit and supplies the supply voltage Va to the control circuit. These additional components make it possible to supply a power-supply voltage Va that is significantly less oscillatory than that occurring at the terminals of the reservoir capacitance Cm, fluctuates in accordance with the charging/discharging cycles, and is linked to the off/on phases of the device 1.

It will be noted that the voltage occurring at the terminals of the reservoir capacitance Cm is nevertheless supplied to the control circuit 4, at a high-impedance measuring input of this circuit, the measurement of this voltage potentially being useful, as explained above, for generating the deactivation signal of the switch 7c when the measured voltage passes a predetermined threshold Vamax or for placing the device in a protected configuration if the measured voltage is below the minimum threshold voltage Vamin.

As is well known per se and shown in FIG. 5, the regulation circuit LDO typically comprises a transistor of which the gate is connected to the output of a reference voltage comparator (such as a bandgap voltage) and of a voltage representative of that occurring at the terminals of the regulated capacitance Cr. The comparator renders the transistor on or off so as to transfer charges of the reservoir capacitance Cm to the regulated capacitance Cr in accordance with the requirement, in such a way that the voltage Va at the terminals of the regulated capacitance Cr is substantially equal to a set-point voltage sufficient for supplying the control circuit 4 and rendering it functional. This set-point voltage is determined by the value of the resistances of a divider bridge, the midpoint voltage of which is compared with the reference voltage.

Rather than integrating this regulation function of the power voltage Va into the power-supply voltage 7 as proposed here, it may be provided that this function is integrated into the control circuit 4. This results in a configuration similar to that shown in FIG. 1.

In general, a switching device according to the present disclosure thus makes it possible to accumulate charge in the reservoir capacitance Cm of the power-supply circuit 7 during the phases in which the device 1 is off. During the phases in which the device 1 is on, the power-supply circuit is isolated from the nodes where a high current flows. The reservoir capacitance Cm will therefore be selected, in such a way that it accumulates sufficient charge to supply the control circuit when the power-supply circuit 7 is isolated. Similarly, the switch 7c will be kept closed long enough, during the phases in which the device 1 is off, to charge the reservoir capacitance Cm sufficiently. In practice, this duration during which the switch 7c is closed may be very short (for example, approximately a few hundred nanoseconds), so as not to limit the ability of the device 1 to switch from one phase to the other at very high frequency.

The present disclosure therefore describes a switching device comprising an internal power-supply circuit that makes it possible to supply the device without requiring any external power source.

It will be noted that the power-supply circuit is not exposed to small voltages (on the order of the avalanche voltage VBR of the low-voltage transistor 6), and so it may consist of components that were easy to manufacture or provide, and thus inexpensive. It is therefore possible to change over, at low cost, from a power supply external to the device.

Naturally, the present disclosure is not limited to the described implementation, and variant embodiments may be applied thereto without departing from the scope of the present disclosure as defined by the claims.

Thus, although the low-voltage transistor 6 and the high-voltage transistor 5 have been shown connected in a cascode configuration, a switching device 1 according to the present disclosure may be implemented in a cascade configuration. In this configuration, the gate of the high-voltage transistor 5 is not connected to the source of the low-voltage transistor 6, and the control circuit 4 thus develops a second control signal IN′ to control the gate of the high-voltage transistor 5. The two signals IN, IN′ will thus be controlled to make it possible to accumulate charges in the power-supply circuit 7 during the phases where the device 1 is off, as has indeed been illustrated in the present description.

A switching device according to the present disclosure can be used in a power conversion system in a half-bridge configuration. As is well known per se, a system of this type comprises a high switcher and a low switcher (each of which may be in accordance with the present disclosure) connected to two connecting terminals. One of these terminals is connected to a source of high continuous voltage and the other to the ground. The two switchers define a midpoint to which a resonant load is connected.

1. A switching device of a load, comprising:
two switching terminals;
a depletion-mode high-voltage transistor and an enhancement-mode low-voltage transistor arranged in series between the two switching terminals and defining a midpoint;
a control circuit generating a control signal of a gate of the low-voltage transistor in order to selectively place the device in an on state or in an off state;
a power-supply circuit comprising an input connected to the midpoint and an output for supplying a power voltage to the control circuit;
the power-supply circuit comprising:
a reservoir capacitance establishing the power voltage supplied to the control circuit when the switching device is connected to the load; and
a normally-on switch, arranged between the input and the reservoir capacitance and suitable for electrically isolating the reservoir capacitance from the midpoint when the switch is open.

2. The switching device of claim 1, wherein the gate of the high-voltage transistor is electrically connected to a source of the low-voltage transistor.

3. The switching device of claim 1, wherein the control circuit generates a second control signal of the gate of the high-voltage transistor.

4. The switching device of claim 3, wherein the switch comprises a depletion-mode low-voltage transistor and a diode electrically connected to the input of the circuit and arranged in series with the depletion-mode low-voltage transistor.

5. The switching device of claim 3, wherein the switch comprises a first depletion-mode low-voltage transistor and a second depletion-mode low-voltage transistor connected in series.

6. The switching device of claim 5, wherein the power-supply circuit further comprises a circuit for regulating the power voltage.

7. The switching device of claim 6, wherein the control circuit is configured to generate a deactivation signal for the switch such that the first control signal is generated to place the device in the on state.

8. The switching device of claim 7, wherein the high-voltage transistor has a threshold voltage greater in absolute value than the power voltage sufficient to render the control device functional.

9. The switching device of claim 8, wherein the control circuit is configured to generate a deactivation signal for the switch when the power voltage exceeds a threshold voltage.

10. The switching device of claim 9, wherein the control circuit is configured to place the device in a protected configuration when the power voltage falls below a minimum threshold voltage.

11. A method for operating a switching device according to claim 1, the method comprising:
using the control circuit to generate a control signal to open the low-voltage transistor and place the switching device in an off phase;
using the control circuit to generate a control signal to close the low-voltage transistor and place the switching device in an on phase; and
using the control circuit to generate a deactivation signal to open the switch of the power-supply circuit at least during the on phase of the switching device.

12. The switching device of claim 1, wherein the switch comprises a depletion-mode low-voltage transistor and a diode electrically connected to the input of the circuit and arranged in series with the depletion-mode low-voltage transistor.

13. The switching device of claim 1, wherein the switch comprises a first depletion-mode low-voltage transistor and a second depletion-mode low-voltage transistor connected in series.

14. The switching device of claim 1, wherein the power-supply circuit further comprises a circuit for regulating the power voltage.

15. The switching device of claim 1, wherein the control circuit is configured to generate a deactivation signal for the switch such that the first control signal is generated to place the device in the on state.

16. The switching device of claim 1, wherein the high-voltage transistor has a threshold voltage greater in absolute value than the power voltage sufficient to render the control device functional.

17. The switching device of claim 1, wherein the control circuit is configured to generate a deactivation signal for the switch when the power voltage exceeds a threshold voltage.

18. The switching device of claim 1, wherein the control circuit is configured to place the device in a protected configuration when the power voltage falls below a minimum threshold voltage.
